(19) United States
(12) Patent Application Publication
(10) Pub. No.: US 2022/0358350 A1
(43) Pub. Date: Nov. 10, 2022

(54) DEEP LEARNING ACCELERATOR MODELS AND HARDWARE

(71) Applicant: Micron Technology, Inc., Boise, ID (US)

(72) Inventors: Poorna Kale, Folsom, CA (US); Saideep Tiku, Fort Collins, CO (US)

(21) Appl. No.: 17/315,045

(22) Filed: May 7, 2021

(51) Int. Cl. G06N 3/063; G06N 3/08; G06N 3/04

(52) U.S. Cl. CPC G06N 3/063; G06N 3/08; G06N 3/04

(57) ABSTRACT

A first deep learning accelerator (DLA) model can be executed using a first DLA chip of a DLA package. The first DLA chip can have a first computational capability and the first DLA model can have a first maximum accuracy value. Responsive to an accuracy value of first results from executing the first DLA model using the first DLA chip being less than a threshold accuracy value, signaling indicative of the first results can be provided directly to a second DLA chip of the DLA package and a second DLA model can be executed using the second DLA chip and the first results as inputs. The second DLA chip can have a second computational capability that is greater than the first computational capability. The second DLA model can have a second maximum accuracy value that is greater than the first maximum accuracy value.

### TECHNICAL FIELD

The present disclosure relates generally to memory, and more particularly to apparatuses and methods associated with executing deep learning accelerator (DLA) models using DLA chips of a DLA package.

### BACKGROUND

Memory devices are typically provided as internal, semiconductor, integrated circuits in computers or other electronic devices. There are many different types of memory including volatile and non-volatile memory. Volatile memory can require power to maintain its data and includes random-access memory (RAM), dynamic random access memory (DRAM), and synchronous dynamic random access memory (SDRAM), among others. Non-volatile memory can provide persistent data by retaining stored data when not powered and can include NAND flash memory, NOR flash memory, read only memory (ROM), Electrically Erasable Programmable ROM (EEPROM), Erasable Programmable ROM (EPROM), and resistance variable memory such as phase change random access memory (PCRAM), resistive random access memory (RRAM), and magnetoresistive random access memory (MRAM), among others.

Memory is also utilized as volatile and non-volatile data storage for a wide range of electronic applications. including, but not limited to personal computers, portable memory sticks, digital cameras, cellular telephones, portable music players such as MP3 players, movie players, and other electronic devices. Memory cells can be arranged into arrays, with the arrays being used in memory devices.

### BRIEF DESCRIPTION OF THE DRAWINGS

FIG. 1 is a block diagram of an apparatus in the form of a computing system including a memory device in accordance with a number of embodiments of the present disclosure.

FIG. 2 is a block diagram of a DLA package including DLA chips in accordance with a number of embodiments of the present disclosure.

FIG. 3 is a block diagram representation of switching between DLA chips of a DLA package in accordance with a number of embodiments of the present disclosure.

FIG. 4 is a block diagram representation of determining when to switch DLA chips in accordance with a number of embodiments of the present disclosure.

FIG. 5 is a flow diagram of a method for executing DLA models using DLA chips of a DLA package in accordance with a number of embodiments of the present disclosure.

FIG. 6 is a flow diagram of a method for executing DLA models using DLA chips of a DLA package in accordance with a number of embodiments of the present disclosure.

FIG. 7 illustrates an example computer system within which a set of instructions, for causing the machine to perform various methodologies discussed herein, can be executed.

### DETAILED DESCRIPTION

The present disclosure includes apparatuses and methods related to executing deep learning accelerator (DLA) models using DLA chips of a DLA package. Artificial intelligence (AI) can be employed on devices and/or systems that have a limited power supply. As used herein, artificial intelligence refers to the ability to improve a machine through “learning” such as by storing patterns and/or examples which can be utilized to take actions at a later time. Deep learning refers to a device's ability to learn from data provided as examples. Deep learning can be a subset of artificial intelligence. Artificial neural networks, among other types of networks, can be classified as deep learning.

Non-limiting examples of AI applications include deep-learning edge applications such as object detection, classification, tracking, and navigation. Deep-learning edge applications can be deployed on unmanned vehicles (e.g., drones) that are dependent on battery-based power supplies. How deep-learning edge applications are deployed on and/or utilized with such power-constrained devices and/or systems is contingent on efficient energy utilization of deep-learning edge applications. Deep-learning edge applications may be executed by DLAs. However, DLAs are not re-configurable or partitioned. During manufacturing, DLAs are produced meeting requirements of a workload, but the DLAs cannot be adapted to changes in the workload post-manufacturing. Some previous approaches to improving energy efficiency of DLAs may include using DLA application specific integrated circuits (ASICs).

Multiple DLA models (e.g., deep learning models) of the same type (e.g., MobileNet, ResNet, VGG19, etc.) may be executed to perform detection and/or classification for a given deep learning task. Each of the DLA models may be deployed on a respective DLA ASIC. The DLA ASICs may have different computational capabilities and/or processing requirements corresponding to computational capabilities and/or processing requirements of the DLA models. As used herein, “computational capability” refers to capability to perform computations whereas “processing requirements” refer to requirements to perform computations.

As used herein, “execution of a DLA model on data” refers to performance of calculations on the data using a DLA chip according to parameters of the DLA model. A DLA model can have parameters (be configured) such that execution of the DLA model yields results of at least a particular confidence value (e.g., accuracy value). As used herein, “accuracy of results yielded from execution of a DLA model” refers to a quantity of correct predictions made by the DLA model relative to a quantity of total predications made by the DLA model. Confidence in particular results yielded from execution of a DLA model can be referred to as, and expressed as, an accuracy value. Examples of parameters of a DLA model include, but are not limited to, a maximum quantity of multiply and accumulate circuits (MACs) of a DLA to be used during execution of the DLA model. Other non-limiting examples of parameters of a DLA model can be a maximum quantity of iterations of computations during execution of the DLA model and a maximum quantity of computations to be performed during execution of the DLA model. In at least one embodiment, execution of a DLA model implemented on a DLA can include utilization of at most a particular quantity (e.g., a subset) of MACs implemented on the DLA. Such parameters of a DLA model can limit the computational capability of the DLA model, which, in turn, can limit the accuracy of results yielded from execution of the DLA model. However, what may be lost in computational capability can be gained in reduced resource consumption.

A DLA model configured to yield high-accuracy results can utilize a greater quantity of MAC, perform a greater quantity of iterations of computations, and/or perform a greater quantity of computations during execution of the DLA model than a different DLA model configured to yield low-accuracy results. Execution of a DLA model configured to yield high-accuracy results can consume more resources than execution of a DLA model configured to yield low-accuracy results. For example, execution of a DLA model configured to yield high-accuracy results can have greater power requirements (greater power consumption) than execution of a DLA model configured to yield results of a lower accuracy.

In some previous approaches, DLA models configured to yield high-accuracy results may be executed in situations that do not require high-accuracy results. Thus, some previous approaches may expend more power executing a DLA model having high computational capability when executing a DLA model having low computational capability yields sufficiently accurate results. Executing a DLA model having high computational capability in such circumstances expends excess power relative to executing a DLA model having low computational capability. In low-power devices, such as Internet-of-Things (IoT) devices, reducing excess power expenditures is important.

Aspects of the present disclosure address the above and other deficiencies. For instance, execution of various DLA models can be assigned to different DLA chips of a DLA package. A DLA chip can include a quantity of DLA cores can be based on the computational capability and/or processing requirements of a DLA model to be executed by the DLA chip. Some embodiments of the present disclosure provide post-manufacturing flexibility not available in previous approaches. For example, a DLA package can include DLA chips having different quantities of DLA cores. An advantage of some embodiments described herein is an ability for on-demand workload aware compute deployment, utilization, and/or management. Computational capability of a DLA chip can be available on-demand and is scalable to satisfy changing requirements of deep-learning edge applications.

As used herein, the singular forms “a”, “an”, and “the” include singular and plural referents unless the content clearly dictates otherwise. Furthermore, the word “may” is used throughout this application in a permissive sense (i.e., having the potential to, being able to), not in a mandatory sense (i.e., must). The term “include,” and derivations thereof, mean “including, but not limited to.” The term “coupled” means directly or indirectly connected.

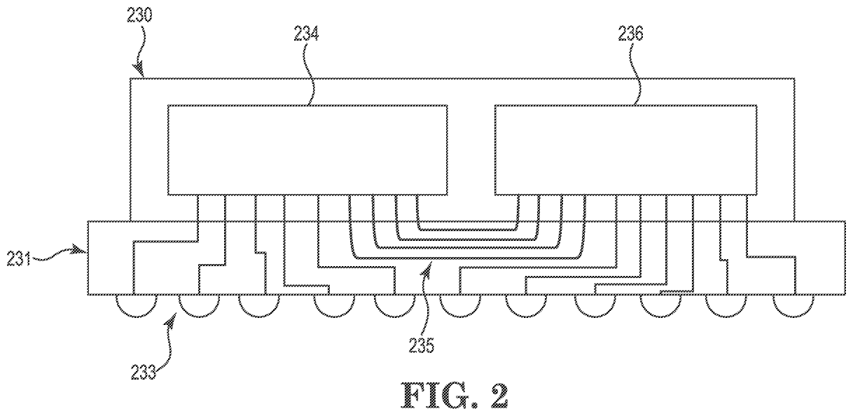

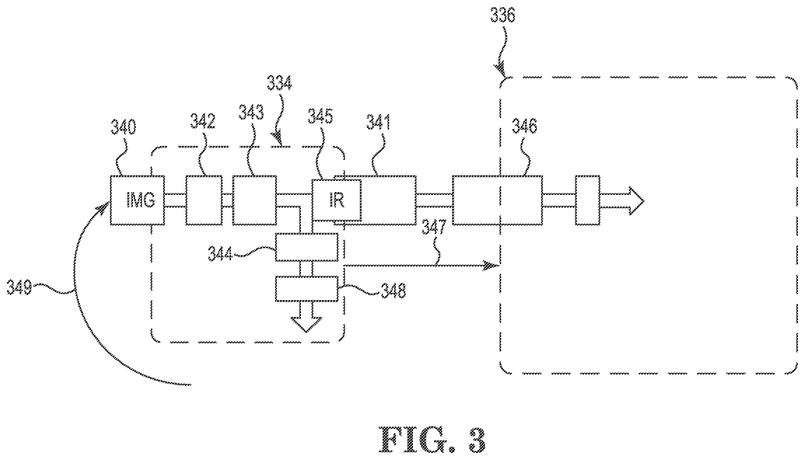

The figures herein follow a numbering convention in which the first digit or digits correspond to the drawing figure number and the remaining digits identify an element or component in the drawing. Similar elements or components between different figures may be identified by the use of similar digits. For example, 234 may reference element “34” in FIG. 2, and a similar element may be referenced as 334 in FIG. 3. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate certain embodiments of the present invention and should not be taken in a limiting sense.

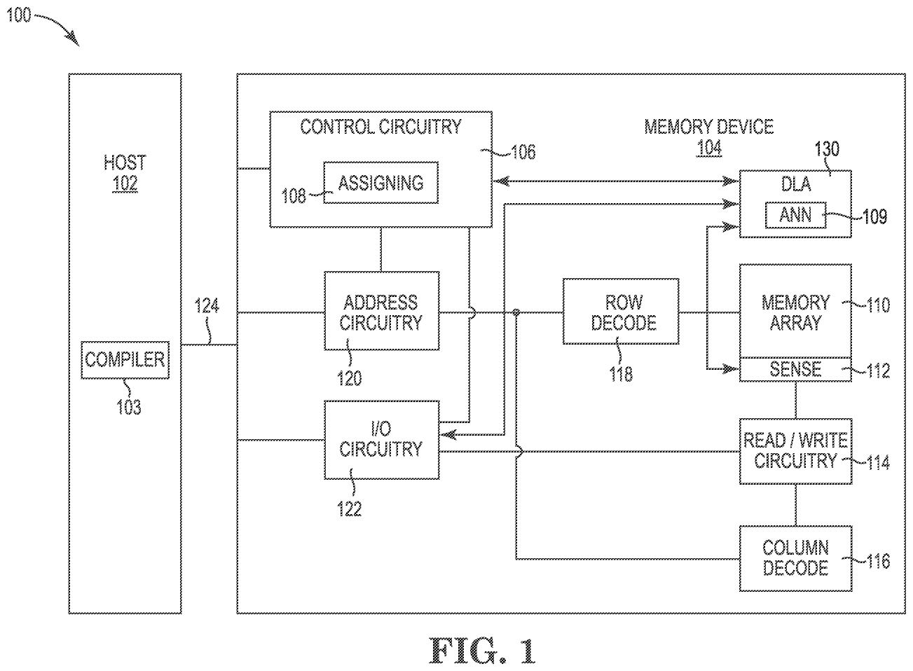

FIG. 1 is a block diagram of an apparatus in the form of a computing system 100 including a memory device in accordance with a number of embodiments of the present disclosure. The memory device 104 is coupled to a host 102 via an interface 124. As used herein, a host 102, a memory device 104, or a memory array 110, for example, might also be separately considered to be an “apparatus.” The interface 124 can pass control, address, data, and other signals between the memory device 104 and the host 102. The interface 124 can include a command bus (e.g., coupled to the control circuitry 106), an address bus (e.g., coupled to the address circuitry 120), and a data bus (e.g., coupled to the input/output (I/O) circuitry 122). In some embodiments, the command bus and the address bus can be comprised of a common command/address bus. In some embodiments, the command bus, the address bus, and the data bus can be part of a common bus. The command bus can pass signals between the host 102 and the control circuitry 106 such as clock signals for timing, reset signals, chip selects, parity information, alerts, etc. The address bus can pass signals between the host 102 and the address circuitry 120 such as logical addresses of memory banks in the memory array 110 for memory operations. The interface 124 can be a physical interface employing a suitable protocol. Such a protocol may be custom or proprietary, or the interface 124 may employ a standardized protocol, such as Peripheral Component Interconnect Express (PCIe), Gen-Z interconnect, cache coherent interconnect for accelerators (CCIX), etc. In some cases, the control circuitry 106 is a register clock driver (RCD), such as RCD employed on an RDIMM or LRDIMM.

The memory device 104 and host 102 can be a satellite, a communications tower, a personal laptop computer, a desktop computer, a digital camera, a mobile telephone, a memory card reader, an IoT enabled device, an automobile, a drone, among various other types of systems. For clarity, the system 100 has been simplified to focus on features with particular relevance to the present disclosure. The host 102 can include a number of processing resources (e.g., one or more processors, microprocessors, or some other type of controlling circuitry) capable of accessing the memory device 104.

The memory device 104 can provide main memory for the host 102 or can be used as additional memory or storage for the host 102. By way of example, the memory device 104 can be a dual in-line memory module (DIMM) including memory arrays 110 operated as double data rate (DDR) DRAM, such as DDR5, a graphics DDR DRAM, such as GDDR6, or another type of memory system. Embodiments are not limited to a particular type of memory device 104. Other examples of memory arrays 110 include RAM, ROM, SDRAM, LPDRAM, PCRAM, RRAM, flash memory, and three-dimensional cross-point, among others. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased.

The control circuitry 106 can decode signals provided by the host 102. The control circuitry 106 can also be referred to as a command input and control circuit and can represent the functionality of different discrete ASICs or portions of different ASICs depending on the implementation. The signals can be commands provided by the host 102. These signals can include chip enable signals, write enable signals, and address latch signals, among others, that are used to control operations performed on the memory array 110. Such operations can include data read operations, data write operations, data erase operations, data move operations, etc. The control circuitry 106 can comprise a state machine, a sequencer, and/or some other type of control circuitry, which may be implemented in the form of hardware, firmware, or software, or any combination of the three.

Data can be provided to and/or from the memory array 110 via data lines coupling the memory array 110 to input/output (I/O) circuitry 122 via read/write circuitry 114. The I/O circuitry 122 can be used for bi-directional data communication with the host 102 over an interface. The read/write circuitry 114 is used to write data to the memory array 110 or read data from the memory array 110. As an example, the read/write circuitry 114 can comprise various drivers, latch circuitry, etc. In some embodiments, the data path can bypass the control circuitry 106.

The memory device 104 includes address circuitry 120 to latch address signals provided over an interface. Address signals are received and decoded by a row decoder 118 and a column decoder 116 to access the memory array 110. Data can be read from memory array 110 by sensing voltage and/or current changes on the sense lines using sensing circuitry 112. The sensing circuitry 112 can be coupled to the memory array 110. The sensing circuitry 112 can comprise, for example, sense amplifiers that can read and latch a page (e.g., row) of data from the memory array 110. Sensing (e.g., reading) a bit stored in a memory cell can involve sensing a relatively small voltage difference on a pair of sense lines, which may be referred to as digit lines or data lines.

The memory array 110 can comprise memory cells arranged in rows coupled by access lines (which may be referred to herein as word lines or select lines) and columns coupled by sense lines (which may be referred to herein as digit lines or data lines). Although the memory array 110 is shown as a single memory array, the memory array 110 can represent a plurality of memory arrays arraigned in banks of the memory device 104. The memory array 110 can include a number of memory cells, such as volatile memory cells (e.g., DRAM memory cells, among other types of volatile memory cells) and/or non-volatile memory cells (e.g., RRAM memory cells, among other types of non-volatile memory cells).

The memory device 104 can include a DLA 130. Hereinafter, the DLA 130 can be referred to as a DLA package. As described herein, the DLA 130 can include multiple DLA chips (e.g., DLA ASICs). The DLA 130 can be implemented on or near an edge of the memory device 104. For example, as illustrated by FIG. 1, the DLA 130 can be implemented external to the memory array 110. The DLA 130 can be on a data path (e.g., an output path) between the memory array 110 to the I/O circuitry 122.

The DLA 130 can be coupled to the control circuitry 106. The control circuitry 106 can control the DLA 130. For example, the control circuitry 106 can provide signaling to the row decoder 118 and the column decoder 116 to cause the transferring of data from the memory array 110 to the DLA 130 to provide an input to the DLA 130. The control circuitry 106 can cause the output of the DLA 130 to be provided to the I/O circuitry 122 and/or be stored back to the memory array 110.

The DLA 130 can be controlled, by the control circuitry 106, for example, to execute an artificial neural network (ANN) 109. A DLA model is a non-limiting example of an ANN. The ANN 109 can include hardware and/or firmware to implement a DLA model for performing operations on data. In some embodiments, the memory device 104 can be configured to store an ANN (e.g., the ANN 109) and the DLA 130 can be used to supplement operation of the ANN for various functions. For example, the DLA 130 and ANN 109 can be used to identify an object in an image and/or changes in images. Data indicative of an image can be input to the DLA 130.

In some embodiments, a compiler 103 can be hosted by the host 102. As used herein, “compiler” refers to hardware and/or software that compiles instructions from a source device to cause an action at a destination device. For example, the compiler 103 can compile instructions from the host 102 to cause the DLA 130 to execute one or more DLA models in accordance with the instructions. As used herein, a “compiler being configured to X” and “compiler being used to X” refers to the compiler compiling instructions to cause X.

As described herein, and particularly in association with FIG. 3, the compiler 103 can be used to determine when to switch from executing a DLA model using a DLA chip of the DLA 130 to a different DLA model using a different DLA chip of the DLA 130. The compiler 103 can include hardware, software, and/or firmware. For example, the compiler 103 can include hardware separate from a processor (not shown) of the host 102. In some embodiments, the compiler 103 can include computer-executable instructions that can be executed by a processor to compile the instructions.

The complied instructions generated by the compiler 103 can be provided to the control circuitry 106 to cause the control circuitry 106 to execute the compiled instructions. Once the compiled instructions are stored in the memory array 110, the host 102 can provide commands to the memory device 104 to execute the compiled instructions utilizing the DLA 130. The compiled instructions can be executed by the DLA 130 to execute the ANN 109. The control circuitry 106 can cause the compiled instructions to be provided to the DLA 130. The control circuitry 106 can cause the DLA 130 to execute the compiled instructions. The control circuitry 106 can cause the output of the DLA 130 to be stored back to the memory array 110, to be returned to the host 102, and/or to be used to perform additional computations in the memory device 104.

The control circuitry 106 can also include switching circuitry 108. In some embodiments, the switching circuitry 108 can comprise an ASIC configured to switch executing DLA models on DLA chips of a DLA package described herein. In some embodiments, the switching circuitry 108 can represent functionality of the control circuitry 106 that is not embodied in separate discrete circuitry. The control circuitry 106 and/or the switching circuitry 108 can be configured to direct execution of respective DLA models by DLA chips of the DLA 130 (. The control circuitry 106 and/or the switching circuitry 108 can be configured to execute a first DLA model using a first DLA chip in response to results having at least a threshold confidence value. The control circuitry 106 and/or the switching circuitry 108 can be configured to execute a second DLA model using a second DLA chip of the DLA package on results from execution of the first DLA model in response to results from execution of the first DLA model having less than the threshold confidence value. The second DLA chip can have a greater computational capability than the first DLA chip.

In some embodiments, the control circuitry 106 can maintain the second DLA chip in a low power state during execution of the first DLA model by the first DLA chip. The control circuitry 106 can cause the second DLA chip to exit the low power state in response to results from execution of the first DLA model having a confidence value less than a threshold confidence value. The first DLA chip can provide the results from execution of the first DLA model to the second DLA chip in response to the results from execution of the first DLA model having a confidence value less than the threshold confidence value.

FIG. 2 is a block diagram of a DLA package 230 including DLA chips 234 and 236 in accordance with a number of embodiments of the present disclosure. The DLA package 230 can be analogous to the DLA 130 described in association with FIG. 1. The DLA chips 234 and 236 can be disposed on a substrate material 231. The DLA chips 234 and 236 can be coupled to conductive lines and pads 233 of the DLA package 230. The DLA chip 234 can be coupled to the DLA chip 236 via conductive lines 235. As illustrated by FIG. 2, the D/LA chip 234 can be directly coupled to the DLA chip 236. The conductive lines 235 can be used to communicate results from the DLA chip 234 to the DLA chip 236 and from the DLA chip 236 to the DLA chip 234.

The DLA chips 234 and 236 can each be an ASIC (e.g., a DLA ASIC). In some embodiments, the DLA chips 234 and 236 can have different computational capabilities and/or processing requirements. For example, the DLA chip 234 can include fewer DLA cores than the DLA chip 236. The DLA chip 234 can include an array of MACs of a size corresponding to processing requirements of the first DLA model. The DLA chip 236 can include an array of MACs of a size corresponding to processing requirements of the second DLA model. The DLA chip 236 can include a larger array of MACs than the DLA chip 234. For example, the DLA chip 234 can include a 256×256 array of MACs and the DLA chip 236 can include a 512×512 array of MACs. Thus, the DLA chip 234 can be referred to as a “little” DLA chip and the DLA chip 236 can referred to as a “big” DLA chip. The DLA chip 234 execute a DLA model having lower computational capability and/or processing requirements whereas the DLA chip 236 can execute a DLA model having higher computational capability and/or processing requirements.

In some embodiments, the DLA chips 234 and 236 can execute respective DLA models concurrently. For example, the DLA chip 234 can execute a DLA model concurrently with execution of another DLA model by the DLA chip 236. In some embodiments, multiple DLA chips can execute the same DLA model and/or DLA models having similar computational capabilities and/or processing requirements concurrently.

In some embodiments, the DLA chip 234 can execute computational layers of a DLA model until the confidence of the results falls below a threshold. In response to the confidence of the results falling below the threshold, another DLA model having higher computational capability and/or processing requirements can be executed by the DLA chip 236 using the results from the DLA chip 234 as input. Such embodiments provide energy savings by not executing a DLA model using the “big” DLA chip 236, which consumes more energy than the “little” DLA chip 234, until the “big” DLA chip 236 is needed.

Although FIG. 2 illustrates the DLA package 230 including two DLA chips, embodiments of the present disclosure are not so limited. In some embodiments, the DLA package 230 can include more than two DLA chips. For example, the DLA package 230 can include three DLA chips. In addition to the DLA chips 234 and 236, a third DLA chip (not shown) can be coupled to the DLA chips 234 and 236 to communicate results from the DLA chips 234 and/or 236 to the third DLA chip and from the third DLA chip to the DLA chips 234 and/or 236. The third DLA chip can have computational capability and/or processing requirements that is greater than those of the DLA chip 234 and lesser than those of the DLA chip 236. For example, the third DLA chip can include more DLA cores than the DLA chip 234 and fewer DLA cores than the DLA chip 236. Thus, the DLA chip 234 can be referred to as a “little” DLA chip, the third DLA chip can be referred to as a “medium” DLA chip, and the DLA chip 236 can referred to as a “big” DLA chip.

FIG. 3 is a block diagram representation of switching between DLA chips 334 and 336 of a DLA package in accordance with a number of embodiments of the present disclosure. The dashed boxes 334 and 336 encompass operations performed by the DLA chips 234 and 236, respectively, described in association with FIG. 2. Although the DLA chips are not specifically illustrated in FIG. 3, reference numbers 334 and 336 are used to refer to the DLA chips.

As illustrated by FIG. 3, an inference of data 340, such as an image, can be input to the DLA chip 334. At 342, 343, and 344, respectively, a computational layer of a DLA model can be executed on the data 340 by the DLA chip 334. In response to results from the third computational layer, at 344, having a confidence value that is less than a threshold confidence value, at 348, an early exit from execution of the DLA model by the DLA chip 334 occurs. As indicated at 349, another inference of the data 340 can be input to the DLA chip 334.

At 345, intermediate results (IR) from execution of the DLA model by the DLA chip 334 can be communicated to the DLA chip 336. In response to results from the third computational layer have a confidence value that is less than a threshold confidence value, at 347, a wake up request can be communicated to the DLA chip 336. In some embodiments, the DLA chip 336 can maintain a low power state until receiving a wake up request and/or intermediate results. For example, power provided to the DLA chip 336 can be reduced below a level necessary for the DLA chip 336 to fully function to maintain a low power state. To provide a fast transition of the DLA chip 336 from a low power state, in some embodiments, initial weights used by the DLA chip 336 can be written to non-volatile SRAM of the DLA package or coupled to the DLA package. In some embodiments, computation modules of the DLA chip 336 can be power gated. At 341 and 346, respectively, a computational layer 341 and 346 of another DLA model can be executed on the intermediate results 345 by the DLA chip 336.

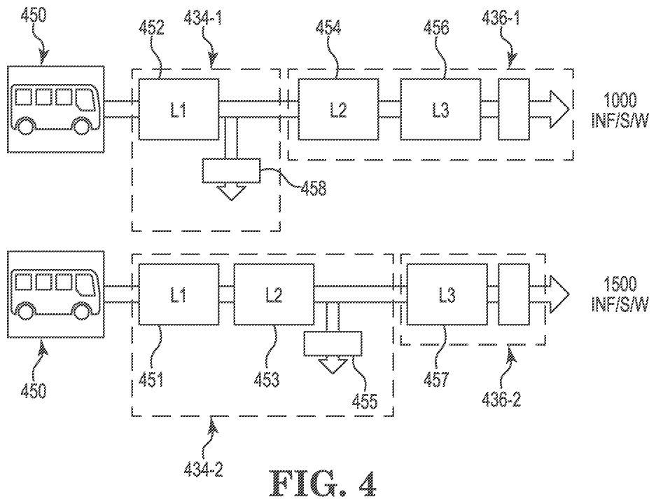

FIG. 4 is a block diagram representation of determining a switch from a DLA chip 434 to another DLA chip 436 in accordance with a number of embodiments of the present disclosure. The dashed boxes 434-1 and 434-2 encompass operations performed by the virtual DLA chip 434 and 436-1 and 436-2 encompass operations performed by the virtual DLA chip 436. The upper portion of FIG. 4 illustrates a sequence of execution of the first DLA model and the second DLA model on the representative data 450 (hereinafter referred to as “the upper sequence”). In FIG. 4, “434-1” and “436-1” refer to operations performed by the virtual DLA chips 444 and 436, respectively, according to the upper sequence. The lower portion of FIG. 4 illustrates a different sequence of execution of the first DLA model and the second DLA model on the representative data 450 (hereinafter referred to as “the lower sequence”). In FIG. 4, “434-2” and “436-2” refers to operations performed by the virtual DLA chips 444 and 436, respectively according to the lower sequence. Although the DLA package and the DLA chips thereof are not specifically illustrated in FIG. 4, reference numbers 430, 434, and 436 are used to refer to the DLA package and the DLA chips, respectively.

As described in association with FIG. 2, in some embodiments, a first DLA model can be executed by a first DLA chip (e.g., the DLA chip 234). Based on confidence (e.g., accuracy) of results from execution of the first DLA model after a compile time, the DLA package 430 can switch from execution of the first DLA model using the first DLA chip to execution of a second DLA model using a second DLA chip (e.g., the DLA chip 236).

In some embodiments, if and when to switch execution of DLA models and corresponding DLA chips can be determined at compile time based on data representative of data on which execution of the DLA models is anticipated (hereinafter referred to as representative data). Instead of determining if and when to switch execution of DLA models and corresponding DLA chips reactively based on confidence of results from execution of the DLA models on data received after compile time, in some embodiments if and when to switch execution of DLA models and corresponding DLA chips can be determined proactively based on execution of DLA models on representative data. Results from execution of the DLA models on the representative data can evaluated (e.g., the confidence of results can be evaluated) to determine if and when to switch execution of DLA models and corresponding DLA chips. A quantity of computational layers of a first DLA model to be executed prior to switching to execution of the second DLA model can be determined.

The representative data 450 can be chosen based on expected data on which DLA models will be executed. In the example of FIG. 4, the DLA package (not shown) is a component of an autonomous vehicle (not shown). Thus, the representative data 450 includes an image of a bus.

At 452 of the upper sequence, computational layer L1 of the first DLA model is executed on the representative data 450 using the DLA chip 434. At 458, an early exit from execution of the first DLA model occurs and the results from execution of the computational layer L1 are input to the second DLA chip 436. At 454 and 456, respectively, two computational layers of the second DLA model, computational layer L2 and computational layer L3, are executed using the second DLA chip 436. The upper sequence yields results having 1,000 inf/s/w.

At 451 and 453 of the lower sequence, respectively, computational layer L1 and computational layer L2 of the first DLA model are executed on the representative data 450 using the DLA chip 434. At 459, an early exit from execution of the first DLA model occurs and the results from execution of the computational layers L1 and L2 are input to the second DLA chip 236. At 457, a computational layer of the second DLA model, computational layer L3, is executed using the second DLA chip 436. The lower sequence yields results having 1,500 inf/s/w. Thus, the lower sequence yields more accurate results than the upper sequence.

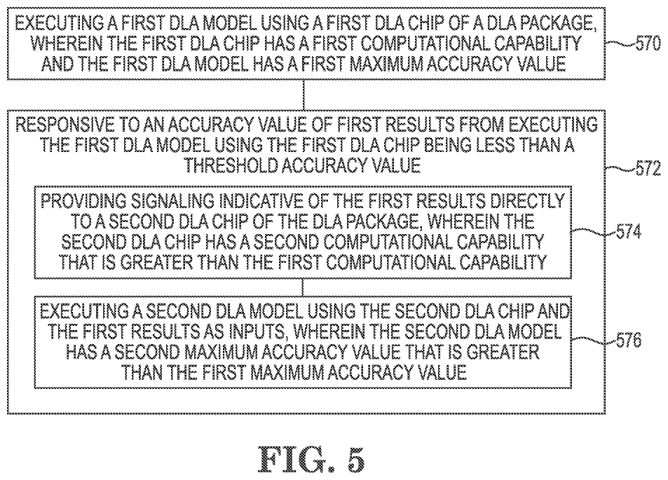

FIG. 5 is a flow diagram of a method for executing DLA models using DLA chips of a DLA package in accordance with a number of embodiments of the present disclosure. The method can be performed by processing logic that can include hardware (e.g., a processing device, circuitry, dedicated logic, programmable logic, microcode, hardware of a device, integrated circuit, etc.), software (e.g., instructions run or executed on a processing device), or a combination thereof. In some embodiments, the method is performed by the control circuitry (e.g., the control circuitry 106 described in association with FIG. 1). Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 570, the method can include executing a first DLA model using a first DLA chip of a DLA package. The first DLA chip can have a first computational capability and the first DLA model can have a first maximum accuracy value.

At block 572, the method can include, responsive to an accuracy value of first results from executing the first DLA model using the first DLA chip being less than a threshold accuracy value, at block 574, providing signaling indicative of the first results directly to a second DLA chip of the DLA package and, at block 576, executing a second DLA model using the second DLA chip and the first results as inputs. The second DLA chip can have a second computational capability that is greater than the first computational capability. The second DLA model can have a second maximum accuracy value that is greater than the first maximum accuracy value.

Although not specifically illustrated, the method can include, responsive to an accuracy value of second results from executing the second DLA model using the second DLA chip being at least a second threshold accuracy value that is greater than the threshold accuracy value, providing signaling indicative of the second results directly to the first DLA chip and executing the first DLA model using the first DLA chip and the second results as inputs. Subsequent to providing signaling indicative of the second results directly to the first DLA chip, power provided to the second DLA chip can be reduced. The method can further include, responsive to an accuracy value of third results from executing the first DLA model using the first DLA chip being at most the threshold accuracy value, providing signaling indicative of the third results directly to the second DLA chip and executing the second DLA model using the second DLA chip and the third results as inputs.

Although not specifically illustrated, the method can include, responsive to an accuracy value of second results from executing the second DLA model using the second DLA chip and the being at most the first threshold accuracy value, providing signaling indicative of the second results directly to a third DLA chip of the DLA package and executing a third DLA model using the third DLA chip and the second results as inputs. The third DLA chip can have a third computational capability that is greater than the second computational capability of the second DLA chip. The third DLA model can have a third maximum accuracy value that is greater than the second maximum accuracy value of the second DLA model.

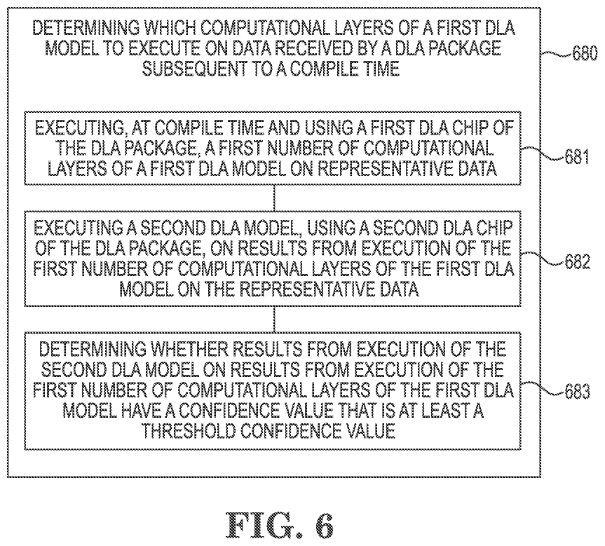

FIG. 6 is a flow diagram of a method for executing DLA models using DLA chips of a DLA package in accordance with a number of embodiments of the present disclosure. The method can be performed by processing logic that can include hardware (e.g., a processing device, circuitry, dedicated logic, programmable logic, microcode, hardware of a device, integrated circuit, etc.), software (e.g., instructions run or executed on a processing device), or a combination thereof. In some embodiments, the method is performed by the control circuitry (e.g., the control circuitry 106 described in association with FIG. 1). Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 680, the method can include determining which computational layers of a first DLA model to execute on data received by a DLA package subsequent to a compile time. Determining which computational layers of the first DLA model to execute can include, at block 681, executing, at compile time and using a first DLA chip of the DLA package, a first number of computational layers of a first DLA model on representative data and, at block 682, executing a second DLA model, using a second DLA chip, on results from execution of the first number of computational layers of the first DLA model on the representative data. The first DLA chip can include a first plurality of DLA cores and the second DLA chip can include a second plurality of DLA cores greater in quantity than the first plurality of DLA cores. Determining which computational layers of the first DLA model to execute can further include, at block 683, determining whether results from execution of the second DLA model on results from execution of the first number of computational layers of the first DLA model have a confidence value that is at least a threshold confidence value.

Although not specifically illustrated, the method can include responsive to determining that the results from execution of the second DLA model on the results from execution of the second number of computational layers of the first DLA model have a confidence value that is at least the threshold confidence value, executing the second number of computational layers of the first DLA model, subsequent to the compile time and using the first DLA chip, on data received by the DLA package. The method can include, responsive to determining that the results from execution of the second DLA model on the results from execution of the first number of computational layers of the first DLA model have a confidence value that is less than the threshold confidence value, executing a second number of computational layers of the first DLA model, using the first DLA chip, on the representative data. The second number of computational layers can include an additional computational layer of the first DLA model or exclude a computational layer of the first number of computational layers. The second DLA model can be executed, using the second DLA chip, on results from execution of the second number of computational layers of the first DLA model on the representative data. Whether results from execution of the second DLA model on results from execution of the second number of computational layers of the first DLA model have a confidence value that is at least the threshold confidence value can be determined.

The method can include, responsive to determining that the results from execution of the second DLA model on the results from execution of the second number of computational layers of the first DLA model have a confidence value that is at least the threshold confidence value, executing, subsequent to the compile time and using the first DLA chip, the second number of computational layers of the first DLA model on data received by the DLA package. The method can include, responsive to determining that the results from execution of the second DLA model on the results from execution of the first number of computational layers of the first DLA model have a confidence value that is less than the threshold confidence value, executing a number of computational layers of the second DLA model, using the second DLA chip, on the results from execution of the second number of computational layers of the first DLA model on the representative data. The number of computational layers of the second DLA model can include an additional computational layer of the second DLA model or exclude a computational layer of the second DLA model executed on the results from execution of the first number of computational layers of the first DLA model.

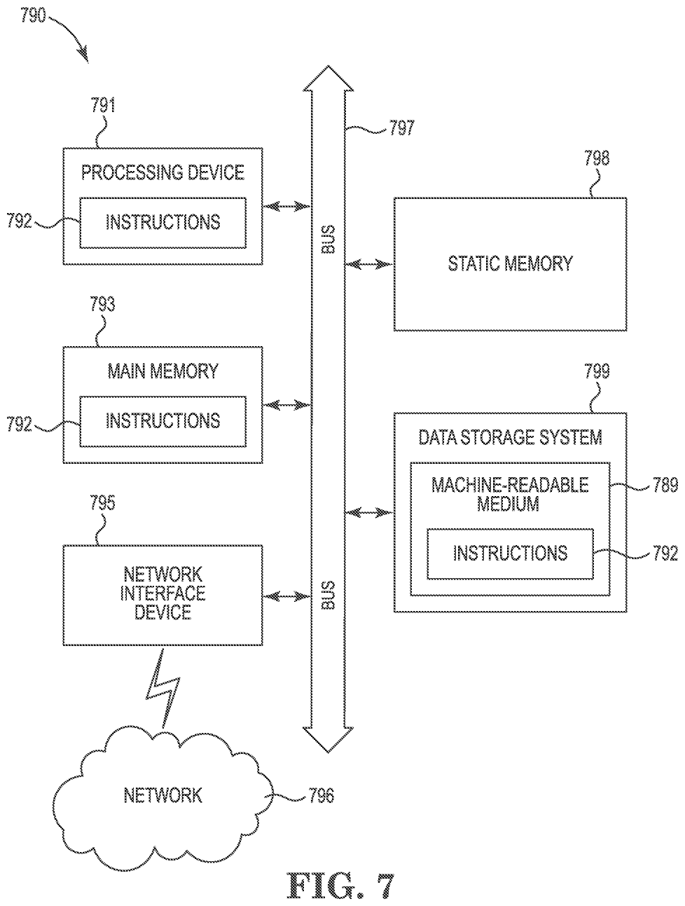

FIG. 7 illustrates an example computer system 790 within which a set of instructions, for causing the machine to perform various methodologies discussed herein, can be executed. In various embodiments, the computer system 790 can correspond to a system (e.g., the computing system 100 described in association with FIG. 1) that includes, is coupled to, or utilizes a memory sub-system (e.g., the memory device 104) or can be used to perform the operations of control circuitry. In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 790 includes a processing device 791, a main memory 793 (e.g., read-only memory (ROM), flash memory, dynamic random access memory (DRAM) such as synchronous DRAM (SDRAM) or Rambus DRAM (RDRAM), etc.), a static memory 797 (e.g., flash memory, static random access memory (SRAM), etc.), and a data storage system 799, which communicate with each other via a bus 797.

The processing device 791 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 791 can also be one or more special-purpose processing devices such as an application specific integrated circuit (ASIC), a field programmable gate array (FPGA), a digital signal processor (DSP), network processor, or the like. The processing device 791 is configured to execute instructions 792 for performing the operations and steps discussed herein. The computer system 790 can further include a network interface device 795 to communicate over the network 796.

The data storage system 799 can include a machine-readable storage medium 789 (also known as a computer-readable medium) on which is stored one or more sets of instructions 792 or software embodying any one or more of the methodologies or functions described herein. The instructions 792 can also reside, completely or at least partially, within the main memory 793 and/or within the processing device 791 during execution thereof by the computer system 790, the main memory 793 and the processing device 791 also constituting machine-readable storage media.

In some embodiments, the instructions 792 include instructions to implement functionality corresponding to the host 102 and/or the memory device 104. The instructions 792 can be executed to cause the machine to determine whether execution of a computational layer of a first DLA model on representative data using a first DLA chip yields results having at least a threshold confidence value. The first DLA chip can include a first plurality of DLA cores. Responsive to determining that execution of the computational layer of the first DLA model, a second DLA model can be executed, using a second DLA chip, on results from execution of the computational layer of the first DLA model. The second DLA chip can include a second plurality of DLA cores that is greater in quantity than the first plurality of DLA cores. The instructions 792 can be executed to cause the machine to determine whether execution of the computational layer of the first DLA model on the representative data yields results having at least the threshold confidence value at a compile time. The instructions 792 can be executed to cause the machine to determine whether the execution of the second DLA model provides at least a threshold quantity of correct inferences per second per watt (inf/s/w).

In some embodiments, the instructions 792 can be executed to cause the machine to determine whether a first confidence value of first results from execution of a first computational layer of a first DLA model is at least a threshold confidence value. A first DLA chip of a DLA package can execute the first DLA model. The instructions 792 can be executed to, responsive to the confidence value being at least the threshold confidence value, execute a second computational layer of the first DLA model using the first results as inputs. The instructions 792 can be executed to, responsive to the first confidence value being less than the threshold confidence value, at block 686, provide signaling indicative of a wake up request to a second DLA chip comprising a greater quantity of DLA cores than the first DLA chip and, at block 688, execute a computational layer of the second DLA model using the results as inputs. The second DLA chip can execute the second DLA model.

The instructions 792 can be executed to, determine whether a second confidence value of second results from execution of the second computational layer of the first DLA model is at least the threshold confidence value. The instructions 792 can be executed to, responsive to the second confidence value being at least the threshold confidence value, a third computational layer of the first DLA model can be executed using the second results as inputs. The instructions 792 can be executed to, responsive to the second confidence value being less than the threshold confidence value, provide the signaling indicative of the wake up request to the second DLA chip and execute the computational layer of the second DLA model using the second results as inputs.

While the machine-readable storage medium 789 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combinations of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

In the foregoing Detailed Description, various features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A method, comprising:
executing a first deep learning accelerator (DLA) model using a first DLA chip of a DLA package, wherein the first DLA chip has a first computational capability and the first DLA model has a first maximum accuracy value; and
responsive to an accuracy value of first results from executing the first DLA model using the first DLA chip being less than a first threshold accuracy value:
providing signaling indicative of the first results directly to a second DLA chip of the DLA package, wherein the second DLA chip has a second computational capability that is greater than the first computational capability; and
executing a second DLA model using the second DLA chip and the first results as inputs, wherein the second DLA model has a second maximum accuracy value that is greater than the first maximum accuracy value.

2. The method of claim 1, further comprising, responsive to an accuracy value of second results from executing the second DLA model using the second DLA chip being at least a second threshold accuracy value that is greater than the first threshold accuracy value:
providing signaling indicative of the second results directly to the first DLA chip; and
executing the first DLA model using the first DLA chip and the second results as inputs.

3. The method of claim 2, further comprising, subsequent to providing signaling indicative of the second results directly to the first DLA chip, reducing power provided to the second DLA chip.

4. The method of claim 1, further comprising, responsive to an accuracy value of second results from executing the second DLA model using the second DLA chip being at most the first threshold accuracy value:
providing signaling indicative of the second results directly to a third DLA chip of the DLA package, wherein the third DLA chip has a third computational capability that is greater than the second computational capability of the second DLA chip; and
executing a third DLA model using the third DLA chip and the second results as inputs, wherein the third DLA model has a third maximum accuracy value that is greater than the second maximum accuracy value of the second DLA model.

5. An apparatus, comprising:
a deep learning accelerator (DLA) package, comprising:
a first DLA chip comprising a first quantity of DLA cores; and
a second DLA chip comprising a second quantity of DLA cores that is greater than the first quantity of DLA cores,
wherein the first DLA chip is coupled to the second DLA chip,
wherein the first DLA chip is configured to execute a first DLA model having a first computational capability, and
wherein the second DLA chip is configured to execute a second DLA model having a second computational capability that is greater than the first computational capability.

6. The apparatus of claim 5, wherein the first DLA chip is further configured to provide, to the second DLA chip, signaling indicative of results from executing the first DLA model, and
wherein the second DLA chip is further configured to execute the second DLA model using the results as inputs.

7. The apparatus of claim 5, wherein the DLA package is configured to, in response to execution of the first DLA model yielding results having a confidence value less than a threshold confidence value:
pause execution of the first DLA model using the first DLA chip;
execute the second DLA model using the second DLA chip.

8. The apparatus of claim 7, wherein the DLA package is further configured to, in response to execution of the second DLA model yielding results having at least the threshold confidence value:
pause execution of the second DLA model; and
resume execution of the first DLA model using the first DLA chip.

9. The apparatus of claim 5, wherein the first DLA chip is directly coupled to the second DLA chip.

10. The apparatus of claim 5, wherein the first DLA chip comprises a first application specific integrated circuit (ASIC), and
wherein the second DLA chip comprises a second ASIC.

11. A non-transitory machine-readable medium storing instructions executable by a processing resource to:
determine whether a first confidence value of first results from execution of a first computational layer of a first deep learning accelerator (DLA) model is at least a threshold confidence value, wherein a first DLA chip of a DLA package executes the first DLA model;
responsive to the first confidence value being at least the threshold confidence value, execute a second computational layer of the first DLA model using the first results as inputs; and
responsive to the first confidence value being less than the threshold confidence value:
provide signaling indicative of a wake up request to a second DLA chip of the DLA package comprising a greater quantity of DLA cores than the first DLA chip; and
executing a computational layer of the second DLA model using the first results as inputs and the second DLA chip.

12. The medium of claim 11, further storing instructions to:
determine whether a second confidence value of second results from execution of the second computational layer of the first DLA model is at least the threshold confidence value;
responsive to the second confidence value being at least the threshold confidence value, execute a third computational layer of the first DLA model using the second results as inputs; and
responsive to the second confidence value being less than the threshold confidence value:
provide the signaling indicative of the wake up request to the second DLA chip; and
execute the computational layer of the second DLA model using the second results as inputs.

13. A system, comprising:
a deep learning accelerator (DLA) package comprising:
a first deep learning accelerator (DLA) chip comprising a first plurality of DLA cores and configured to execute a first DLA model; and
a second DLA chip coupled to the first DLA chip and comprising a second plurality of DLA cores greater in quantity than the first plurality of DLA cores and configured to execute a second DLA model on results from execution of the first DLA model; and
control circuitry coupled the DLA package and configured to maintain the second DLA chip in a low power state during execution of the first DLA model by the first DLA chip.

14. The system of claim 13, wherein the control circuitry is further configured to provide first signaling to the DLA package to cause the second DLA chip to exit the low power state in response to results from execution of the first DLA model having a confidence value less than a threshold confidence value, and
wherein the first DLA chip is further configured to provide second signaling to the second DLA chip indicative of the results from execution of the first DLA model in response to the results from execution of the first DLA model having a confidence value less than the threshold confidence value.

15. The system of claim 13, wherein the first DLA chip comprises a first array of multiply and accumulate circuits (MACs) of a first size corresponding to processing requirements of the first DLA model, and
wherein the second DLA chip comprises a second array of MACs of a second size corresponding to processing requirements of the second DLA model, wherein the second array of MACs is larger than the first array of MACs.

16. The system of claim 15, wherein the first array of MACs comprises a 256 by 256 array of MACs, and
wherein the second array of MACs comprises a 512 by 512 array of MACs.

17. The system of claim 13, wherein the first DLA chip is directly coupled to the second DLA chip.

18. A non-transitory machine-readable medium storing instructions executable by a processing resource to:
determine whether execution of a computational layer of a first deep learning accelerator (DLA) model on representative data, using a first DLA chip, yields results having at least a threshold confidence value,
wherein the first DLA chip comprises a first plurality of DLA cores;
responsive to determining that execution of the computational layer of the first DLA model yields results having less than the threshold confidence value, execute a second DLA model, using a second DLA chip, on results from execution of the computational layer of the first DLA model,
wherein the second DLA chip comprises a second plurality of DLA cores that is greater in quantity than the first plurality of DLA cores.

19. The medium of claim 18, further storing instructions to determine whether execution of the computational layer of the first DLA model on the representative data yields results having at least the threshold confidence value at a compile time.

20. The medium of claim 18, further storing instructions to determine whether the execution of the second DLA model provides at least a threshold quantity of correct inferences per second per watt.

21. A method, comprising:
determining which computational layers of a first deep learning accelerator (DLA) model to execute on data received by a DLA package subsequent to a compile time by:
executing, at the compile time and using a first DLA chip of the DLA package, a first number of computational layers of a first DLA model on representative data;
executing a second DLA model, using the second DLA chip of the DLA package, on results from execution of the first number of computational layers of the first DLA model on the representative data,
wherein the first DLA chip comprises a first plurality of DLA cores and the second DLA chip comprises a second plurality of DLA cores greater in quantity than the first plurality of DLA cores; and
determining whether results from execution of the second DLA model on results from execution of the first number of computational layers of the first DLA model have a confidence value that is at least a threshold confidence value.

22. The method of claim 21, further comprising, responsive to determining that the results from execution of the second DLA model on the results from execution of the first number of computational layers of the first DLA model have a confidence value that is at least the threshold confidence value:
executing, subsequent to the compile time and using the first DLA chip, the first number of computational layers of the first DLA model on data received by the DLA package; and
executing the second DLA model on results from execution of the first number of computational layers of the first DLA model.

23. The method of claim 22, further comprising, responsive to determining that the results from execution of the second DLA model on the results from execution of the first number of computational layers of the first DLA model have a confidence value that is less than the threshold confidence value:
executing, using the first DLA chip, a second number of computational layers of the first DLA model on the representative data, wherein the second number of computational layers includes an additional computational layer of the first DLA model or excludes a computational layer of the first number of computational layers;
executing, using the second DLA chip, the second DLA model on results from execution of the second number of computational layers of the first DLA model on the representative data; and
determining whether results from execution of the second DLA model on results from execution of the second number of computational layers of the first DLA model have a confidence value that is at least the threshold confidence value.

24. The method of claim 23, further comprising, responsive to determining that the results from execution of the second DLA model on the results from execution of the second number of computational layers of the first DLA model have a confidence value that is at least the threshold confidence value:
executing, subsequent to the compile time and using the first DLA chip, the second number of computational layers of the first DLA model on data received by the DLA package.

25. The method of claim 23, further comprising, responsive to determining that the results from execution of the second DLA model on the results from execution of the first number of computational layers of the first DLA model have a confidence value that is less than the threshold confidence value:
executing a number of computational layers of the second DLA model, using the second DLA chip, on the results from execution of the second number of computational layers of the first DLA model on the representative data,
wherein the number of computational layers includes an additional computational layer of the second DLA model or excludes a computational layer of the second DLA model executed on the results from execution of the first number of computational layers of the first DLA model.
